(19) United States
(12) Patent Application Publication
(10) Pub. No.: US 2021/0109808 A1
(43) Pub. Date: Apr. 15, 2021

(54) Using Original Data as Soft Bit Information in a Decoder

(71) Applicant: Western Digital Technologies, Inc., San Jose, CA (US)

(72) Inventor: Refael BEN-RUBI, Rosh Haayin (IL)

(21) Appl. No.: 16/601,876

(22) Filed: Oct. 15, 2019

(51) Int. Cl. G06F 11/10; H03M 13/11; G11C 16/04; G11C 16/26; G11C 16/34

(52) U.S. Cl. CPC G06F 11/1068; H03M 13/1102; G11C 16/3459; G11C 16/26; G11C 16/0483

(57) ABSTRACT

The present disclosure uses a previously written version of the current data being read as input to a decoder, to increase the probability of reading a correct value from a cell. When the current version of the data is being read by the SSD from a NAND, the data is read as a hard-bit. Using header information, the SSD reads a previously written version of the data as soft-bits. A decoder uses the hard-bits and soft-bits to determine the value of a data bit from a cell. As the cell values from a previously written version of the data are used as soft-bits, the probability that the decoder will return the proper value for the cell is increased.

### BACKGROUND OF THE DISCLOSURE

### Field of the Disclosure

Embodiments of the present disclosure generally relate to reading data from a non-volatile memory, and more particularly to error correction during a read operation from a non-volatile memory.

### Description of the Related Art

When data is written to a solid-state memory, such as a flash memory, the data isn't always stored in the manner intended. Transistors, such as floating gate transistors, may be loaded with different amounts of charge, for example, due to heat in the device, the passage of time, location of a memory component on a die, natural degradation of charge, and a variety of other causes of change in charge. Change in charge within a transistor introduces errors into the information stored in the flash memory, resulting in bit error rate (BER), a metric known to those of skill in the art of solid-state memory devices (SSDs).

One method to solve BER is the cell voltage distribution (CVD) model to identify errors in cells. Using CVD, the cells in a physical memory page are modeled to incorporate different attributes of different cells, in order to determine a threshold voltage at which a cell has a high probability of containing a bit of information. CVD models different groups of cells at different peak voltages. Different peak voltages may apply to different groups of cells due to a variety of factors such as location of a group on a page relative to a die boundary layer, cell groups at different temperatures, cell content of cell groups.

Once cells are grouped using CVD, a number of cells are sampled to determine the lowest threshold in a group that can distinguish between cells containing a low or high bit.

During a data read, thresholds for multiple groups and the voltage readings from each cell in concomitant groups are provided to a decoder. The decoder attempts to provide the intended data value from a cell to a host, and if an error is detected, correct the error.

However, decoders may only be able to fix a limited number of errors. For example, a low density parity check decoder (LDPC) can decode 4k bytes, it can only correct 400 errors, whereas a page may contain 16k bytes of data. In some circumstances, such as high device heat, the number of errors may overwhelm the LDPC's ability to correct errors.

Given that modern SSDs are constantly relocating data in a series of read and write operations, the need to detect and correct errors at scale becomes increasingly important as the amount of data on the device increases.

What is needed is a system and method to provide more accurate data to the LDPC so that a correct data value for a cell may be determined, to avoid generation of errors that need to be corrected.

### SUMMARY OF THE DISCLOSURE

The present disclosure uses a previously written version of the current data being read as input to a decoder, to increase the probability of reading a correct value from a cell. When the current version of the data is being read by the SSD from a NAND, the data is read as a hard-bit. Using header information, the SSD reads a previously written version of the data as soft-bits. A decoder uses the hard-bits and soft-bits to determine the value of a data bit from a cell. As the cell values from a previously written version of the data are used as soft-bits, the probability that the decoder will return the proper value for the cell is increased.

In one embodiment, a data storage device is disclosed. The data storage device includes a memory and a controller configured to perform a method of error correction. In embodiments, the method includes relocating original data to a different location in the memory to create current data, receiving a request from a host for current data, reading current data from memory as hard-bits, and reading the original data as soft-bits. The hard-bits and soft-bits are provided to a decoder, and the decoder decodes the current data using the hard-bits and soft-bits in some embodiments, and then the decoded current data is provided to the hose.

In another embodiment, a data storage device is disclosed. The data storage device includes an interface configured to communicate with a host, a memory, and a decoder communicatively coupled to the host via the interface. In embodiments the decoder may be configured to obtain current data voltage values in the memory, obtain original data voltage values from cells in the memory. The decoder may be further configured to decode the current data voltage values, using original data voltage values for error detection, in some embodiments. The decoded data may provided to the host.

In another embodiment, a system for error correction in a data storage device. In embodiments, the system includes a memory means comprising original data comprising soft-bits and current data comprising hard-bits, a decoder means configured to receive the hard-bits and soft-bits. The decoder may be further configured to decode the hard-bits and soft-bits to generate data. An interface means provides the data to a host.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts an exemplary embodiment of a device in accordance with disclosed embodiments.

FIG. 2 depicts an exemplary functional block diagram in accordance with disclosed embodiments.

FIG. 3 depicts an exemplary method in accordance with disclosed embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure uses a previously written version of the current data being read as input to a decoder, to increase the probability of reading a correct value from a cell. When the current version of the data is being read by the SSD from a NAND, the data is read as a hard-bit. Using header information, the SSD reads a previously written version of the data as soft-bits. A decoder uses the hard-bits and soft-bits to determine the value of a data bit from a cell. As the cell values from a previously written version of the data are used as soft-bits, the probability that the decoder will return the proper value for the cell is increased.

Within a SSD device, NAND packages consist of dies, that include planes, which contain blocks, which in turn contain pages. Within pages are individual cells that store bits of data, and each bit may be stored in a transistor, such as a floating gate transistor. A bit of data in a transistor is represented as a voltage level in the transistor. Although a device has a typical voltage level for different bits of data, the actual voltage in a cell may vary from a reference or expected voltage. Variations in cell voltage may be due to temperature of the cell, location of the cell on the die (e.g. location near an edge of the die vs near the center), manufacturing anomalies, degradation of voltage due to the natural loss of charge over time, and a variety of other factors.

When the SSD performs a read operation, such as when a host device requests data or when data is relocated on a NAND within the SSD, or other device or component requests data from the SSD, the SSD detects voltages in a cell to effectuate the read. A hard-bit is a voltage at/above a reference voltage indicating that the data value stored is a particular value (e.g. 1 or 0) with very high probability. A soft-bit is a voltage measured at a fractional reference voltage, indicating that the data value in the cell has a good probability of being a particular value (e.g. a 1 or 0). A decoder, such as a low density parity check decoder (LDPC), uses the hard-bits and soft-bits to ‘decode’ the data value of a cell to determine a stored value (e.g. 1 or 0) to return in response to a data request. In the event a value cannot be determined, or an incorrect value is determined (e.g. via CRC), an error is generated that may be corrected by the LDPC. However, the LDPC may in some embodiments, only be able to correct a limited number of errors. Given the volume of cells in a modern SSD that need to be decoded, and the constant relocation of data within an SSD, errors in the decoding process are to be avoided. In some cases, too many errors are generated than can be corrected, overwhelming the error correction capability of the LDPC. Embodiments of the present disclosure seek to reduce the number of errors by using original data as soft-bits to increase the likelihood that hard bits of current data are properly decoded.

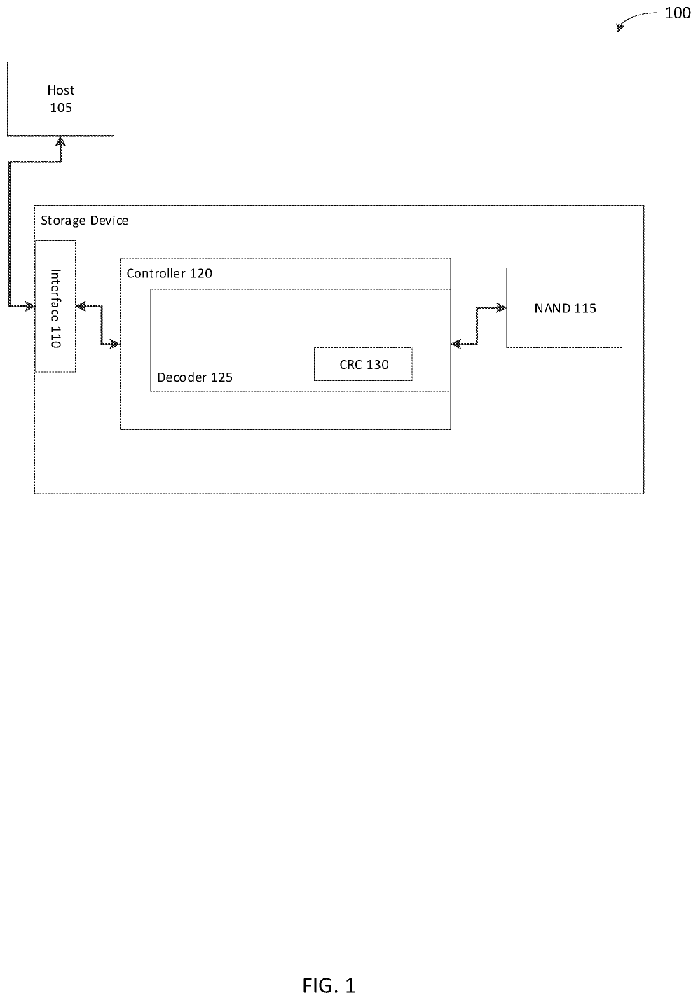

FIG. 1 depicts a data storage device 100 according to disclosed embodiments. Host 105 represents a computer system to which data storage device 100 is operatively connected. Host 105 may be any type of compute device or system capable of requesting computer-readable information, and may be connected to the data storage device 100 via a bus, a network, or any combination of techniques that may enable the host 105 to obtain computer readable information from the data storage device 100. Interface 110 operatively couples the data storage device 100 to the host 105. NAND 115, in embodiments, is a flash-type solid state memory, but may be any type of solid state memory capable of storing computer readable information. NAND 115 may be physically comprised of dies that include planes that in turn include blocks of pages. Each page contains individual cells that may be floating gate transistors, or any type of transistor suitable for storing voltages representative of computer readable information.

Data storage device 100 includes controller 120 that controls its operations. Decoder 125, in some embodiments, is located within controller 120. In embodiments decoder 125 is a firmware-implemented form of error correction code, such as a low density parity check decoder (LDPC), while in other embodiments decoder 125 may be a Bose Chaudhuri and Hocquenghem (BCH) decoder, or other decoder capable of ensuring the accuracy of data read from the NAND 115. Decoder 125 includes a cyclic redundancy check (CRC) 130 in some embodiments to detect, and potentially correct, erroneous data produced by the decoder 125.

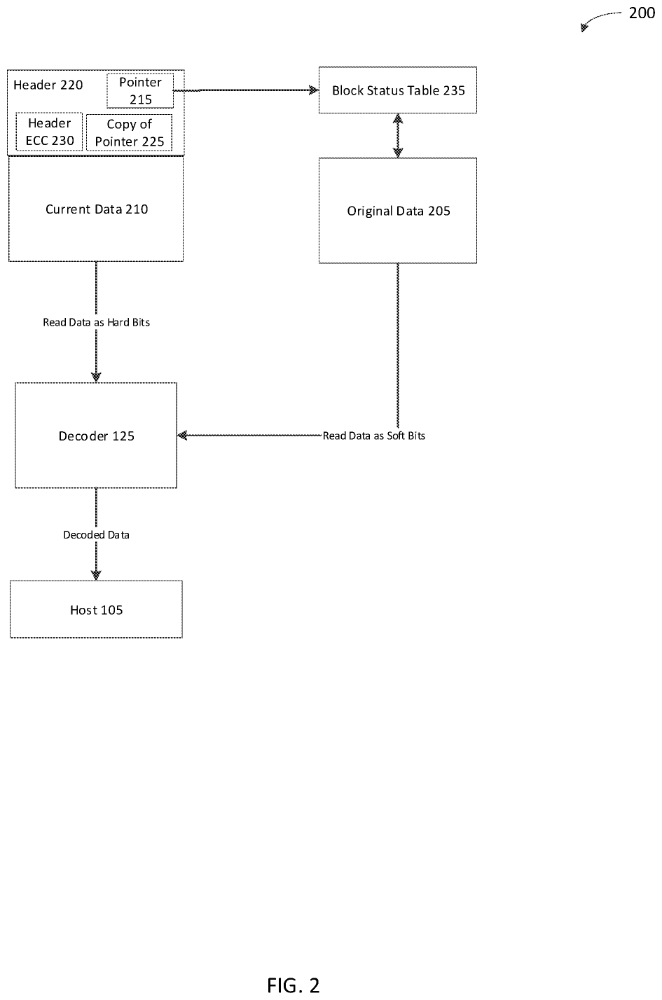

FIG. 2 depicts a functional block diagram 200 according to disclosed embodiments. Original data 205 may be data received from host 105, or other source external to the data storage device 100. For purposes of this disclosure, original data 205 is the data from which current data 210 is copied; stated otherwise, current data 210 is the then-current version of the original data 205. Current data 210 may result from relocation of original data 205, and one skilled in the art will appreciate that in some embodiments SSD data is routinely relocated as part of normal operation.

When original data 205 is copied to current data 210, a pointer 215 is added to a header 220 of current data 210, in some embodiments. Pointer 215 points to the original data 205, by pointing to the physical location of the original data 205 on the NAND 115, by pointing to a location in memory that redirects to original data 205, or any virtual or actual location on the data storage device 100 that resolves to the location of the original data 205 on the NAND 115.

When the data storage device 100 receives a data request (e.g. from the host 105, from the controller 120 to relocate data on the NAND 115, etc.), the decoder 125 reads the header 220 of the current data 210 to follow pointer 215 to original data 205. In some embodiments, decoder 125 will verify that the blocks containing the original data 205 by consulting a block status table 235. Block status table 235 in embodiments is maintained by the controller 120 to track the status of blocks within the NAND 115, tracking if a block contains valid data from which current data was copied (e.g. original data 205), or if the block does not contain valid data (e.g. marked as erased or overwritten).

Decoder 125 reads current data 210 as hard-bits, and if the block status table 235 has indicated that the original data 205 is valid, decoder 125 reads the original data 205 as soft-bits. The hard-bits and soft-bits are combined by the decoder 125 to form data that may be provided to the requestor (e.g. host 105, controller 120, or other system).

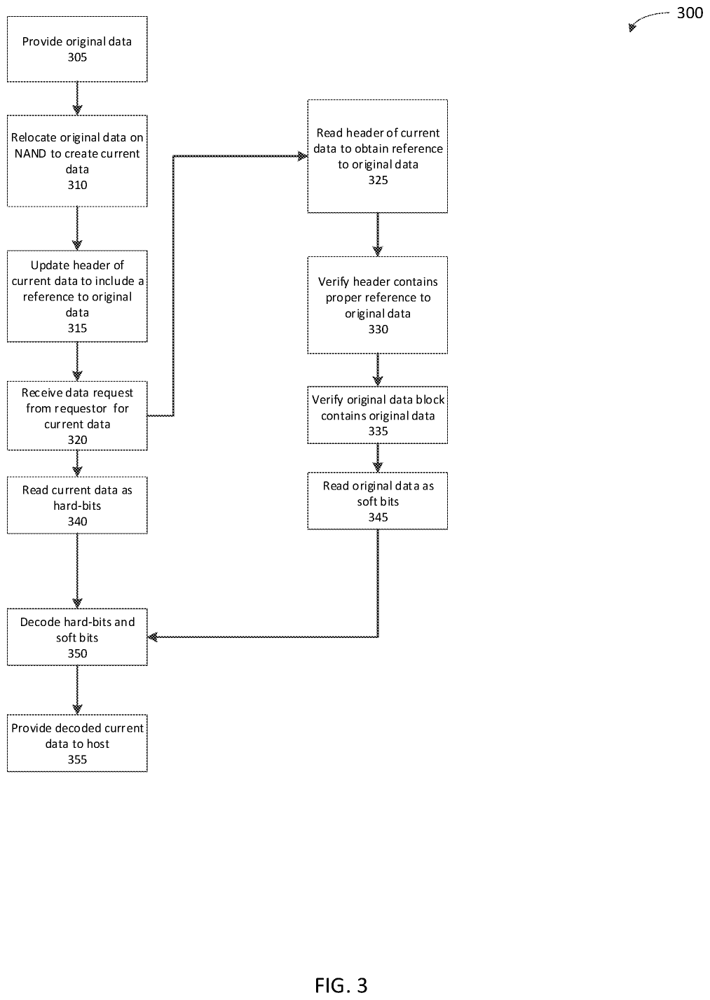

FIG. 3 depicts a method 300 according to disclosed embodiments. At 305, original data 205 is provided in the NAND 115.

At 310, original data 205 is relocated on the NAND 115. The relocated data in embodiments is current data 210.

At 315, the header 220 of current data 210 is updated to reference the original data 205, such as via a pointer 215.

At 320, a data read request is received at the data storage device 100, for the current data 210. The data read request may be a request from host 105 for data, a data relocation request from controller 120, or request from another system or component, external or internal to data storage device 100.

At 325, the method 300 reads the header 220 of the current data 210 to obtain the pointer 215 to the original data 205.

At 330, the decoder 125 of the controller 120 verifies the header 220 contains a correct pointer 215 to the original data 205. In some embodiments, header 220 contains a copy of pointer 225, comparing the copy of pointer 225 to pointer 215, to verify the pointer 215 is correct. In other embodiments, header 220 comprises a header ECC 230 to verify that the header 220 and its contents, such as pointer 215.

At 335, the block(s) where original data 205 reside are verified to contain original data 205. In embodiments, controller 120, or decoder 125, maintains the block status table 235 that tracks the status of blocks. If the status of the blocks comprising original data 205 is marked in the block status table 235 as valid (e.g. contains original data 205), then the method may proceed. If the status of the blocks comprising the original data 205 is marked as invalid (e.g. erased or overwritten), and in embodiments data identified at these invalid table entries are not utilized as soft-bits.

At 340, voltages from cells containing current data 210 is read as hard-bits.

At 345, voltages from cells containing original data 205 is read as soft-bits.

At 350, the hard-bits and soft-bits are decoded in the decoder 125, to provide decoded data and at 355, the decoded data is provided to the requestor.

The preceding description is provided to enable any person skilled in the art to practice the various embodiments described herein. The examples discussed herein are not limiting of the scope, applicability, or embodiments set forth in the claims. Various modifications to these embodiments will be readily apparent to those skilled in the art, and the generic principles defined herein may be applied to other embodiments. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, the word “exemplary” means “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the embodiments shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

In the systems and methods disclosed herein, original data may be used as a soft-bit to verify current data in a decoder, reducing the number of errors produced by the decoder.

In one embodiment, a data storage device is disclosed. The data storage device includes a memory and a controller configured to perform a method of error correction. In embodiments, the method includes relocating original data to a different location in the memory to create current data, receiving a request from a host for current data, reading current data from memory as hard-bits, and reading the original data as soft-bits. The hard-bits and soft-bits are provided to a decoder, and the decoder decodes the current data using the hard-bits and soft-bits in some embodiments, and then the decoded current data is provided to the hose.

In another embodiment, a data storage device is disclosed. The data storage device includes an interface configured to communicate with a host, a soled state memory, and a decoder communicatively coupled to the host via the interface. In embodiments the decoder may be configured to obtain current data voltage values in the memory, obtain original data voltage values from cells in the memory. The decoder may be further configured to decode the current data voltage values, using original data voltage values for error detection, in some embodiments. The decoded data may provided to the host.

In another embodiment, a system for error correction in a data storage device. In embodiments, the system includes a memory means comprising original data comprising soft-bits and current data comprising hard-bits, a decoder means configured to receive the hard-bits and soft-bits. The decoder may be further configured to decode the hard-bits and soft-bits to generate data. An interface means provides the data to a host.

While the foregoing is directed to embodiments of the present disclosure, other and further embodiments of the disclosure may be devised without departing from the basic scope thereof, and the scope thereof is determined by the claims that follow.

What is claimed is:

1. A data storage device comprising:
a memory;
a controller configured to perform a method for error correction, the method comprising:
relocating original data to a different location in the memory to create current data;
receiving a request from a host for current data;
reading current data from the memory as hard-bits;
reading the original data from the memory as soft-bits;
providing the hard-bits and soft-bits to a decoder;
decoding the current data using the hard-bits and soft bits; and
providing the decoded current data to the host.

2. The data storage device of claim 1, wherein a header of the current data is modified to contain a first reference to the original data.

3. The data storage device of claim 2, the original data is read using the reference to the original data.

4. The data storage device of claim 2, wherein the header is verified to contain a proper reference to the original data by performing error correction on the header.

5. The data storage device of claim 2, wherein the header is modified to create a second reference to the original data, the method further comprising verifying the reference to the original data based on one of the first reference and second reference.

6. The data storage device of claim 1, further comprising updating a block status table to indicate that a block containing the original data has not been erased or overwritten.

7. The data storage device of claim 6, further comprising validating that the original data is present via the block status table.

8. The data storage device of claim 1, wherein the decoder comprises a Low Density Parity Check decoder.

9. The data storage device of claim 1, wherein the memory is a NAND.

10. A data storage device comprising:
an interface configured to communicate with a host;
a memory;
a decoder communicatively coupled to the host via the interface, configured to:
obtain current data voltage values from cells in the memory;
obtain original data voltage values from cells in the memory;
decode current data voltage values, using original data voltage values for error detection; and
provide decoded data to the host.

11. The data storage device of claim 10, wherein the decoder is further configured to obtain a reference to the location of the original data voltage values in the memory.

12. The data storage device of claim 11, wherein the decoder is further configured to verify the reference with an error correction code.

13. The data storage device of claim 10, wherein the decoder is further configured to maintain a block status table indicating the status of cells comprising the original data voltage values.

14. The data storage device of claim 13, wherein the block status table comprises a status of one of containing the original data voltage value, erased, and overwritten.

15. A system for error correction in a data storage device, the system comprising:
a memory means comprising original data comprising soft-bits and current data comprising hard bits;
a decoder means configured to receive the hard-bits and soft-bits, and further configured to decode the hard-bits and soft-bits to generate data; and
an interface means to provide the data to a host.

16. The system of claim 15, wherein the current data is a copy of the original data.

17. The system of claim 15, further comprising a block status table, the block status table configured to track the status of the original data as one of valid, erased, and overwritten.

18. The system of claim 15, wherein the current data comprises a header, the header comprising reference to the original data, and a means to verify the reference to the original data.

19. The system of claim 18, wherein the header further comprises an ECC to validate the contents of the header.

20. The system of claim 15, wherein the decoder means comprises one of a Low Density Parity Check decoder and a Bose Chaudhuri and Hocquenghem decoder.
